(19) United States
(12) Patent Application Publication
(10) Pub. No.: US 2009/0034213 A1
(43) Pub. Date: Feb. 5, 2009

(54) Printed Circuit Board and Related Method Capable of Suppressing Electromagnetic Wave

(76) Inventor: Lung-Fai Tuen, Taipei Hsien (TW)

Correspondence Address: NORTH AMERICA INTELLECTUAL PROPERTY CORPORATION, P.O. BOX 506, MERRIFIELD, VA, 22116, US

(21) Appl. No.: 12/136,783

(22) Filed: Jun. 11, 2008

(30) Foreign Application Priority Data
Jul. 30, 2007 (TW) 096127728

(51) Int. Cl. H05K 1/18

(52) U.S. Cl. 361/748

(57) ABSTRACT

A method for suppressing an electromagnetic wave of noise of a printed circuit board comprises forming a metal conducting circuit in a conducting layer of the printed circuit board; and duplicating a plurality of pattern circuits, every two neighboring patterns with substantially the same patterns and separated space for forming a metal conducting circuit that is an electromagnetic wave suppressing circuit having an electromagnetic wave stop frequency band corresponding to the electromagnetic wave of noise.

### BACKGROUND OF THE INVENTION

1. Field of the Invention

The invention relates to a printed circuit board and related method capable of suppressing electromagnetic wave of noise, and more particularly, to a printed circuit board and related method by forming periodically arranged patterns in a conducting layer of the printed circuit board for suppressing the electromagnetic wave of noise.

2. Description of the Prior Art

A printed circuit board, or PCB, is a support for circuit elements of an electronic product, and provides electrical connections between the circuit elements. With the current trends of electronic products toward high frequency and small size, the circuit density of the printed circuit board becomes higher and higher, and thus issues of electromagnetic interference (EMI) and electromagnetic compatibility (EMC) among the circuit elements also become increasingly important. Therefore, the design of the printed circuit board affects the anti-interference ability of the electronic device a lot. Generally, even if the circuit design is correct, but the layout of the printed circuit board is designed inappropriately, the performance and the reliability of the electronic product could also be affected adversely.

As for the design of the printed circuit board, basic wiring principles such as the appropriate electronic element distribution, the layout design of power layers and ground layers, or the layout design of signal lines, can generally be applied for reducing the emission intensity of signal noises and enhancing the circuit stability against the noises. On the other hand, the electromagnetic interference can also be reduced by installing passive components such as noise eliminating capacitors (e.g. decoupling capacitors or bypass capacitors), common mode inductors and common mode filters in the printed circuit board. However, the noise suppression effects that can be reached by these conventional measures are limited, and moreover, additional components often need to be used, so that the space requirements of the printed circuit board has to be increased as well as the production cost of the electronic product.

### SUMMARY OF THE INVENTION

It is therefore a primary objective of the present invention to provide a printed circuit board and related method capable of suppressing electromagnetic wave.

The present invention discloses a method for suppressing an electromagnetic wave of a printed circuit board. The method comprises forming a metal conducting circuit in a conducting layer of the printed circuit board; and duplicating a plurality of pattern circuits, every two neighboring patterns with substantially the same patterns and separated space for forming a metal conducting circuit that is an electromagnetic wave suppressing circuit having an electromagnetic wave stop frequency band corresponding to the electromagnetic wave of noise.

The present invention further discloses a printed circuit board capable of suppressing electromagnetic wave of noise. The printed circuit board comprises a conducting layer; and a metal conducting circuit, laid in the conducting layer, forming a plurality of pattern circuits, every two neighboring patterns with substantially the same patterns and separated space for forming a metal conducting circuit that is an electromagnetic wave suppressing circuit having an electromagnetic wave stop frequency band corresponding to the electromagnetic wave of noise.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a process for a printed circuit board suppressing electromagnetic wave of noise according to the present invention.

FIG. 2 is a schematic diagram of a printed circuit board capable of suppressing electromagnetic wave of noise according to an embodiment of the present invention.

FIG. 3 is an equivalent circuit diagram of the periodically arranged pattern circuits in FIG. 2.

FIG. 4 is a schematic diagram of a measurement system used in experiments of the present invention.

FIG. 5 is a circuit diagram of the noise generation circuit in FIG. 4.

FIG. 6 is a schematic diagram of a metal conducting circuit according to an embodiment of the present invention applied in an experiment of the present invention.

FIG. 7 is a schematic diagram of a conventional metal conducting circuit applied in the experiment of the present invention.

FIG. 8 and FIG. 9 are schematic diagrams of experimental measurement results of the present invention.

FIG. 10 is a schematic diagram of a metal conducting circuit of another embodiment of the present invention applied in the experiment of the present invention.

FIG. 11 and FIG. 12 are schematic diagrams of another experimental measurement results of the present invention.

### DETAILED DESCRIPTION

To make it clear that in the spirit of the present invention, a brief introduction of principles of photonic crystals are illustrated in the following first. The so-called photonic crystals are substantially dielectric material structures having periodically changed dielectric coefficients. Owing to the periodical structure, a band gap phenomenon similar to band structures of electrons also exists in a photonic crystal system. In other words, when fabricating in space a periodically arranged dielectric material structure, having a scale close to wavelengths of electromagnetic waves of noise, the behavior of the electromagnetic waves will act as that of matter waves of electrons does in an atomic lattice, which generates constructive and destructive interferences in different directions according to the period of the periodic structure, space construction and the dielectric coefficients of the dielectric materials. Therefore, the electromagnetic waves of noise within particular frequency ranges will be decreased exponentially due to the destructive interferences, with a result that the electromagnetic waves of the particular frequency ranges cannot propagate in the periodical dielectric structure, which shows the so-called band gap phenomenon in frequency spectrums. In the present invention, the above-mentioned concept is then implemented in a printed circuit board for suppressing the generation of electromagnetic noises, so as to prevent from the electromagnetic interference problem.

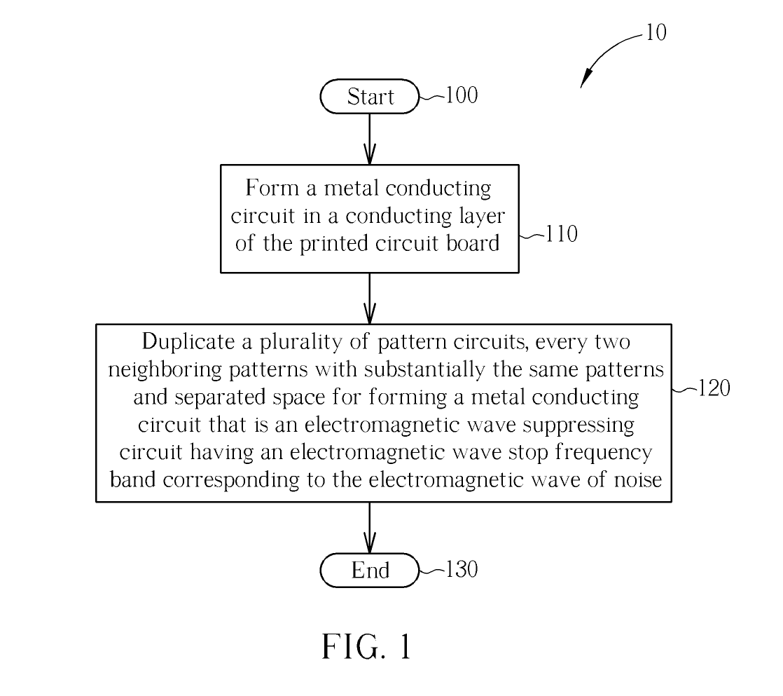

Please refer to FIG. 1. FIG. 1 is a schematic diagram of a process 10 for suppressing electromagnetic waves of noise of a printed circuit board according to the present invention. The process 10 includes the following steps.

Step 100: Start.

Step 110: Form a metal conducting circuit in a conducting layer of the printed circuit board.

Step 120: Duplicate a plurality of pattern circuits, every two neighboring patterns with substantially the same patterns and separated space for forming a metal conducting circuit that is an electromagnetic wave suppressing circuit having an electromagnetic wave stop frequency band corresponding to the electromagnetic wave of noise.

Step 130: end.

According to the process 10, the present invention can form a metal conducting circuit in a conducting layer of the printed circuit board, and adjust the shape of the metal conducting circuit to form a plurality of pattern circuits, every two neighboring patterns with substantially the same patterns and separated space for forming a metal conducting circuit that is an electromagnetic wave suppressing circuit having an electromagnetic wave stop frequency band corresponding to the electromagnetic wave of noise. Preferably, the printed circuit board of the present invention is a multilayer printed circuit board, and thus the conducting layer can be a ground layer or a power layer of the printed circuit board.

Therefore, when designing the layout of the printed circuit board, the present invention can adjust the shape of the metal conducting circuit in the power layer or the ground layer of the printed circuit board to form the periodically arranged pattern circuits according to the frequency of the electromagnetic wave of noise, for being equivalent to a filtering circuit corresponding to the frequency of the electromagnetic wave of noise, so that the electromagnetic wave stop band corresponding to the electromagnetic noises can further be generated. Thus, the present invention simply needs a slight amendment to the power layers or the ground layers of the printed circuit board in the conventional layout framework to achieve the required effect of noise suppression. Compared with the prior art, the present invention not only can save circuit elements, such as coupling capacitors and common mode chokes, significantly, but also can reduce space requirements of the printed circuit board, so as to further save the production cost effectively.

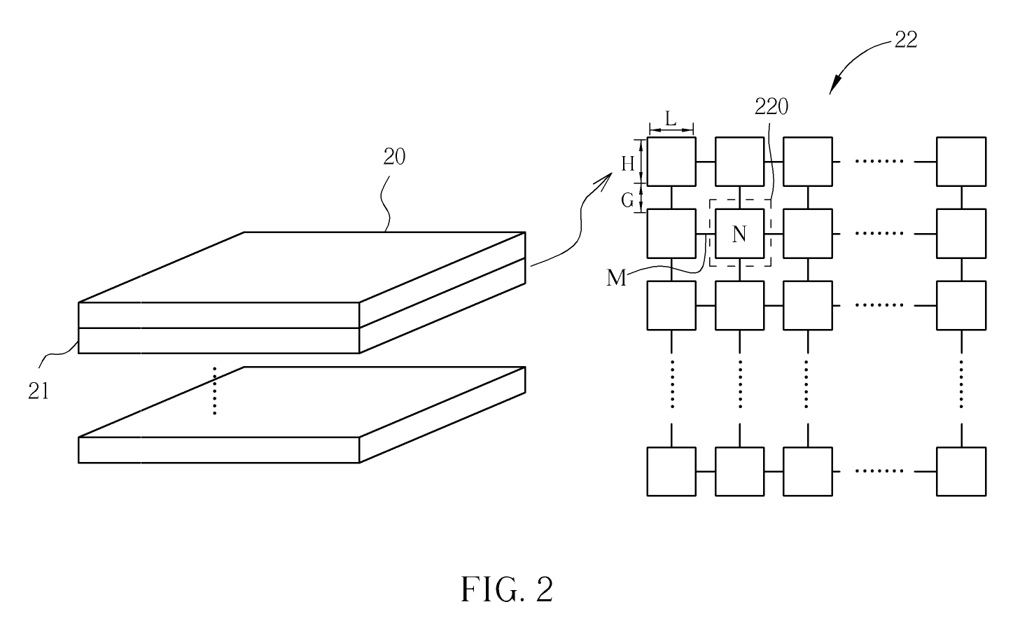

Please refer to FIG. 2. FIG. 2 is a schematic diagram of a printed circuit board 20 capable of suppressing electromagnetic wave of noise according to an embodiment of the present invention. The printed circuit board 20 is a multilayer printed circuit board designed according to the process 10, and includes a conducting layer 21 laid with a metal conducting circuit 22. The metal conducting circuit 22 is formed with periodically arranged pattern circuits 220 for generating an electromagnetic wave stop band corresponding to a frequency of the electromagnetic wave of noise. In the embodiment, one rectangle N and four connecting lines M form each of the periodically arranged pattern circuits 220. As shown in FIG. 2, L and H represent lengths and widths of the rectangles N, and spacing intervals between each of the rectangles N are represented by G. From the perspective of the equivalent circuit, on the metal conducting circuit 22, each rectangle N is equivalent to a capacitance, and each connecting line M is equivalent to an inductance. Meanwhile, spacing between each two rectangles can further couple to form an equivalent capacitance. Thus, for the current loop of the printed circuit board 20, the periodically arranged pattern circuits 220 can be equivalent to the filtering circuit corresponding to the frequency of the electromagnetic wave of noise.

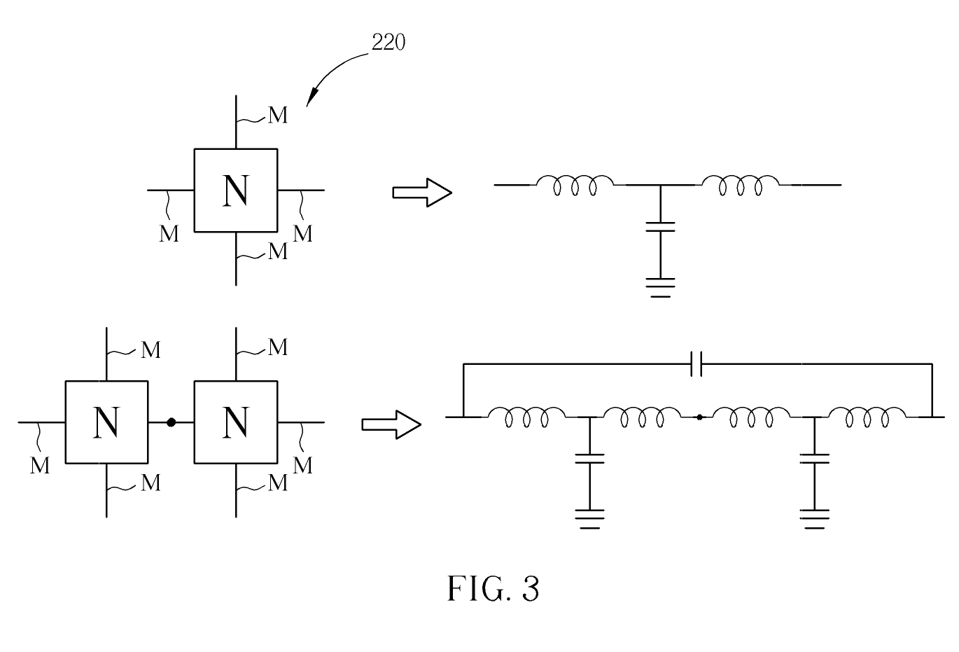

Please refer to FIG. 3. FIG. 3 is an equivalent circuit diagram of the periodically arranged pattern circuits 220 in FIG. 2. General speaking, for suppressing the occurrence of signal noises, the current loop capacitance needs to be increased. Thus, when designing the pattern shape of the periodically arranged pattern circuits 220, the area of each rectangle N has to be increased as much as possible and the spacing interval G between each rectangle has to be reduced as much as possible, for the aim of increasing the capacitance of the current loop. However, such doings is merely a general design rule, and practically, the pattern shape, dimensions and quantity of the periodically arranged pattern circuits 220 can be roughly estimated according to the frequency of the electromagnetic noises and then adjusted by experimental results or through numerical simulations to meet actual demands. For example, when the frequency of the electromagnetic wave of noise being suppressed is 10 GHz, the present invention determines the pattern shape and the dimensions of the periodically arranged pattern circuits 220 according to the wavelength of the electromagnetic wave of noise (i.e. about 3 cm), and then performs detailed adjustments by experimental results or through numerical simulations to achieve the best noise suppression effect.

Please note that, the printed circuit board 20 can further include signal layers, via holes, blind via holes and so on (not show in FIG. 2) for laying signal wires and connecting signal wires between different layers, respectively, which are well known by those skilled in the art and thus not narrated herein. Besides, the pattern shape of the periodically arranged pattern circuits 220 is not limited, and appropriate modifications can certainly be made by designers according to practical demands, which also belong to the range of the present invention.

Therefore, by forming the periodically arranged pattern circuits in the conducting layers of the printed circuit board, such as the power layers or the ground layers, the present invention can generate the electromagnetic wave stop band corresponding to the frequency of the electromagnetic noises for achieving the suppression effect of the electromagnetic wave of noise. In addition, the present invention simply needs slight amendment for the power layer or the ground layer of the printed circuit board in the conventional layout framework. Compared with the prior art, the present invention not only can save passive circuit components such as coupling capacitors and common mode chokes significantly, but also can reduce space requirements of the printed circuit board, so that the production cost can further be saved effectively.

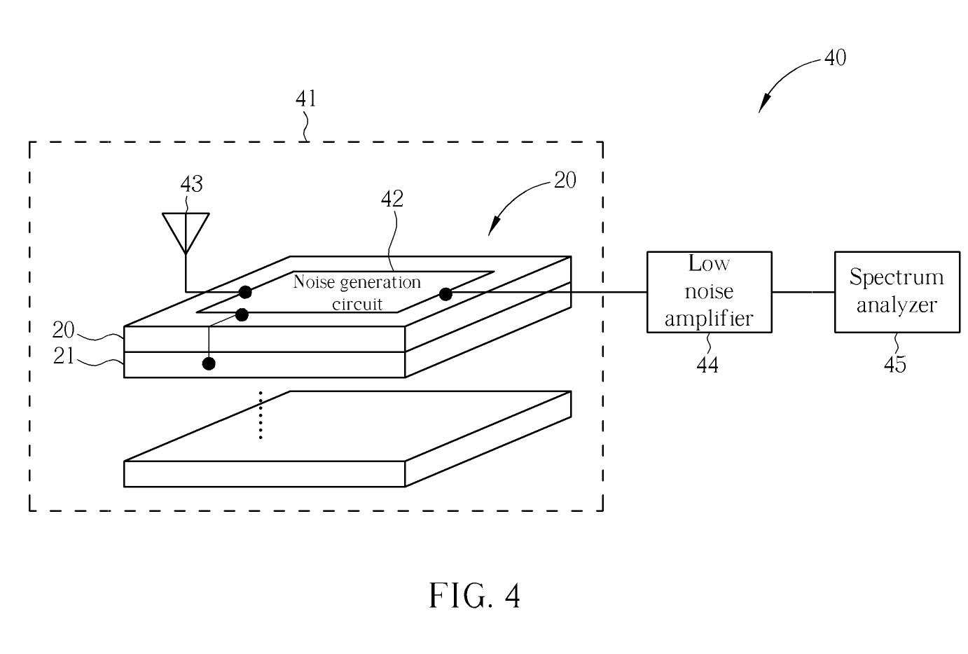

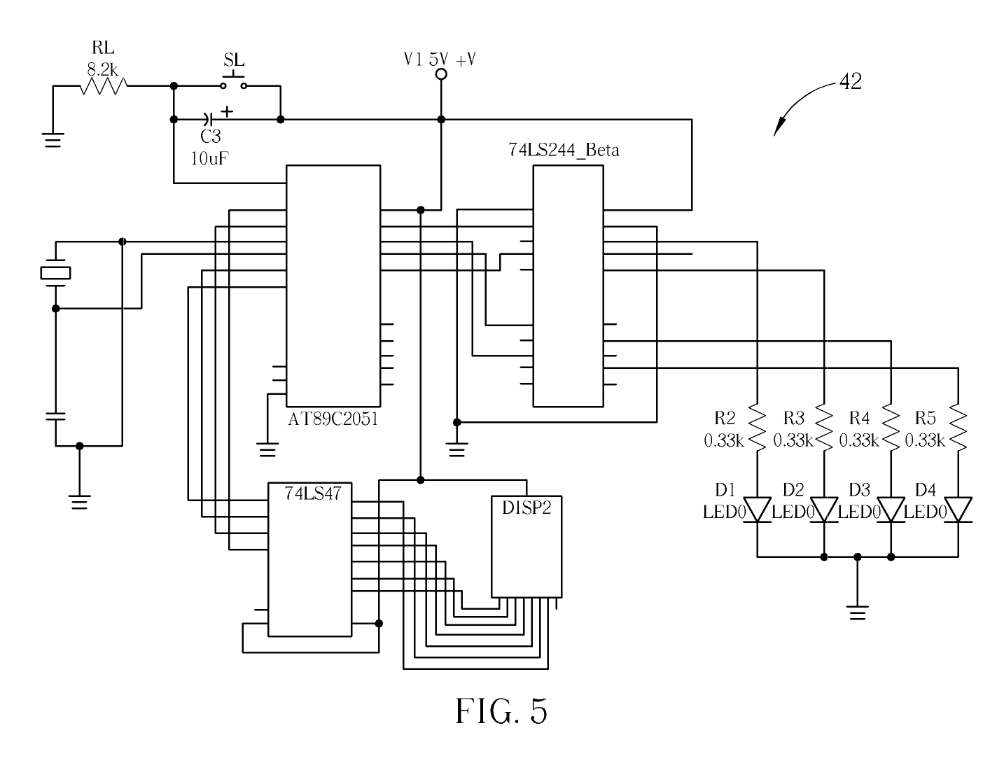

In order to make the present invention more enforceable, concrete experiments are illustrated in the following according to the present invention, and certainly, the present invention is not limited herein. Please refer to FIG. 4. FIG. 4 is a schematic diagram of a measurement system 40 used in experiments of the present invention. The measurement system 40 includes an electromagnetic shielding box 41, a noise generation circuit 42, an antenna 43, a low noise amplifier (LNA) 44 and a spectrum analyzer 45. The noise generation circuit 42 is set on the printed circuit board 20, which includes a micro-controller unit (MCU) for generating clock signals of 1 MHz and 4 MHz and its high frequency harmonic noises as well. Please refer to FIG. 5. FIG. 5 is a circuit diagram of the noise generation circuit 42 in FIG. 4. As shown in FIG. 4, a power supply of the noise generation circuit 42 is coupled to a power layer 21 of the printed circuit board 20. The antenna 43 is also set on the printed circuit board 20, and is utilized for receiving the electromagnetic noises, generated from the printed circuit board 20 and spread in the electromagnetic shielding box 41. The low noise amplifier 44 is coupled between the antenna 43 and the spectrum analyzer 45, and is utilized for amplifying the electromagnetic noises received by the antenna 43 and outputting amplification results to the spectrum analyzer 45. Thus, with the measurement system 40, the electromagnetic noises generated by the printed circuit board 20 can then be spectrum analyzed by the spectrum analyzer 45 for observing the electromagnetic wave of noise's suppression effect of the printed circuit board 20.

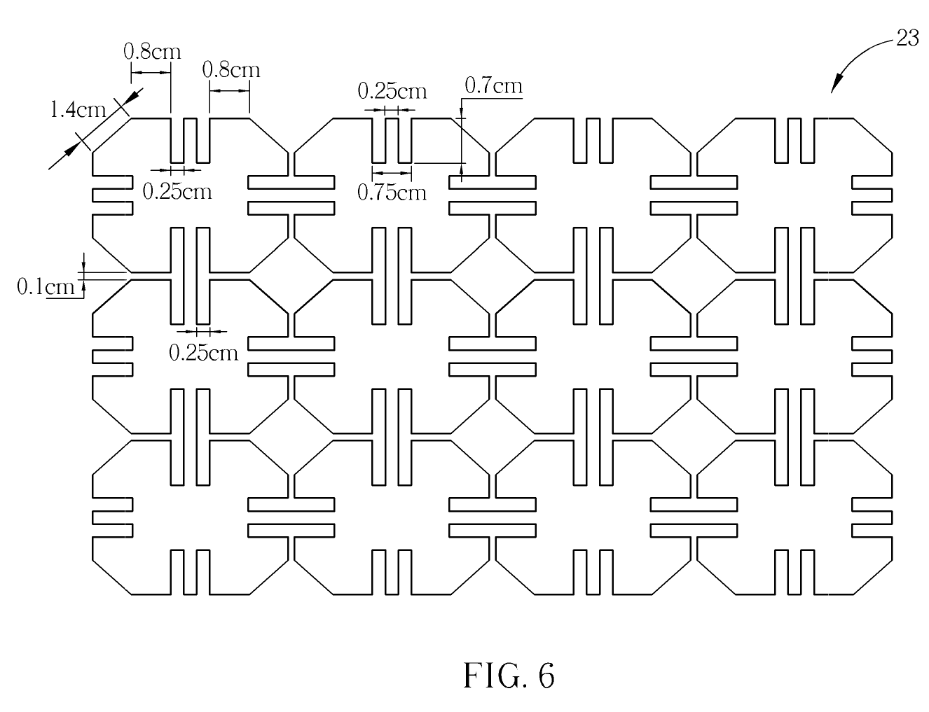

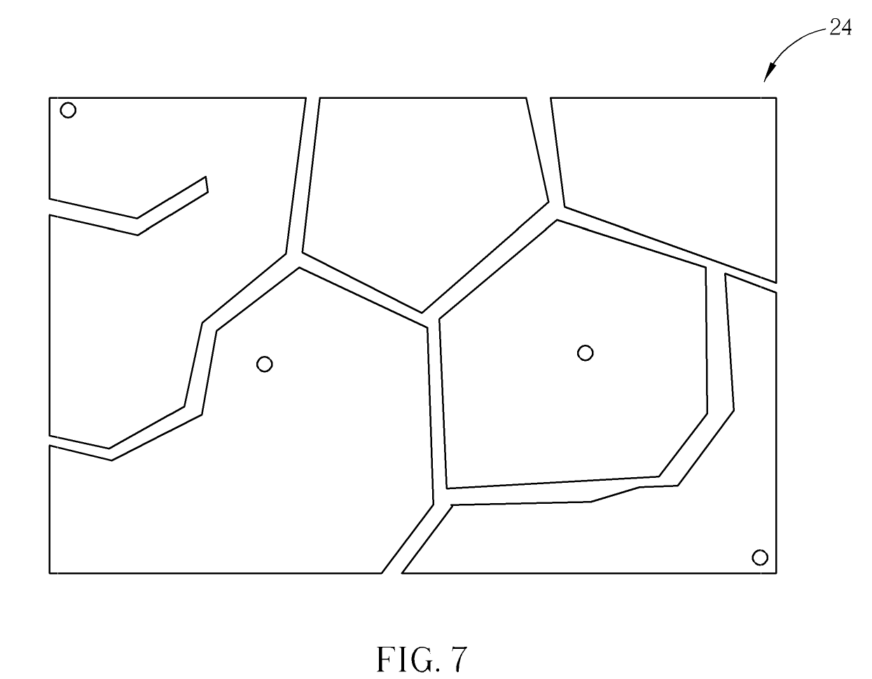

Please refer to FIG. 6. FIG. 6 is a schematic diagram of a metal conducting circuit 23 according to an embodiment of the present invention applied in an experiment of the present invention. The metal conducting circuit 23 is similar to the metal conducting circuit 22, and is laid in the power layer 21 of the printed circuit board 20. Compared with the metal conducting circuit 22, each of periodically arranged pattern circuits 230 in the metal conducting circuit 23 is varied from a square, and further includes four cut corners and eight slots for enhancing the equivalent circuit capacitance of the periodically arranged pattern circuits 230. Dimensions corresponding to each part of the metal conducting circuit 23 are labeled in FIG. 6. Owing that spacing between each slot and each cut corner of the metal conducting circuit 23 can be considered as a equivalent capacitor, and thus for the current loop of the printed circuit board, the equivalent capacitance of the metal conducting circuit 23 can be increased significantly, so as to suppress high-frequency electromagnetic wave of noise effectively. Besides, please refer to FIG. 7. FIG. 7 is a schematic diagram of a conventional metal conducting circuit 24 applied in the experiment of the present invention. The metal conducting circuit 24 conforms to a power layer framework of the conventional printed circuit board, which includes irregular patterns for partitioning different circuit blocks of the conventional printed circuit board. Therefore, in the experiment of the present invention, the metal conducting circuit 24 is utilized as an experimental reference group.

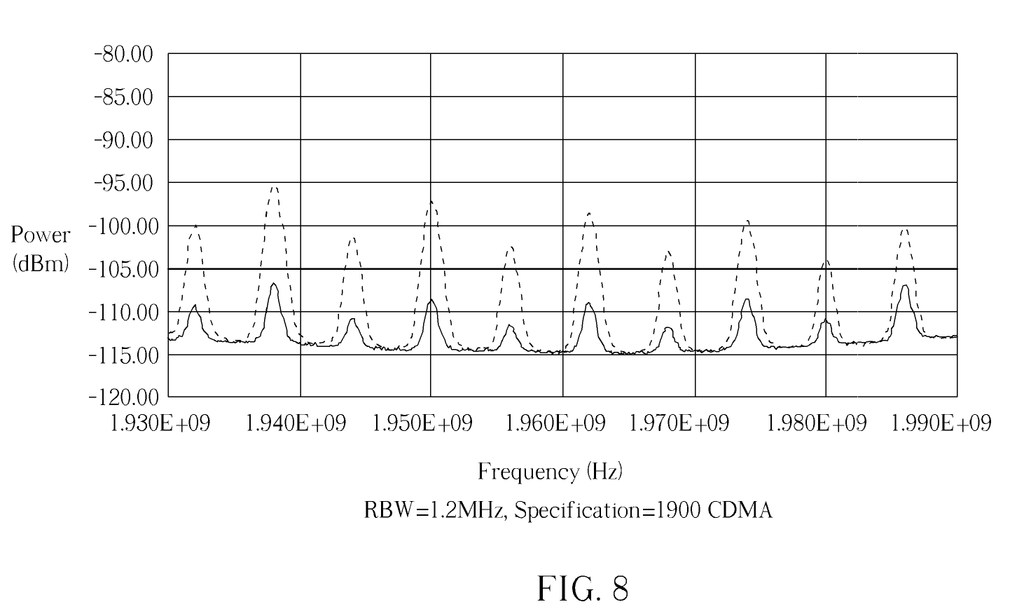

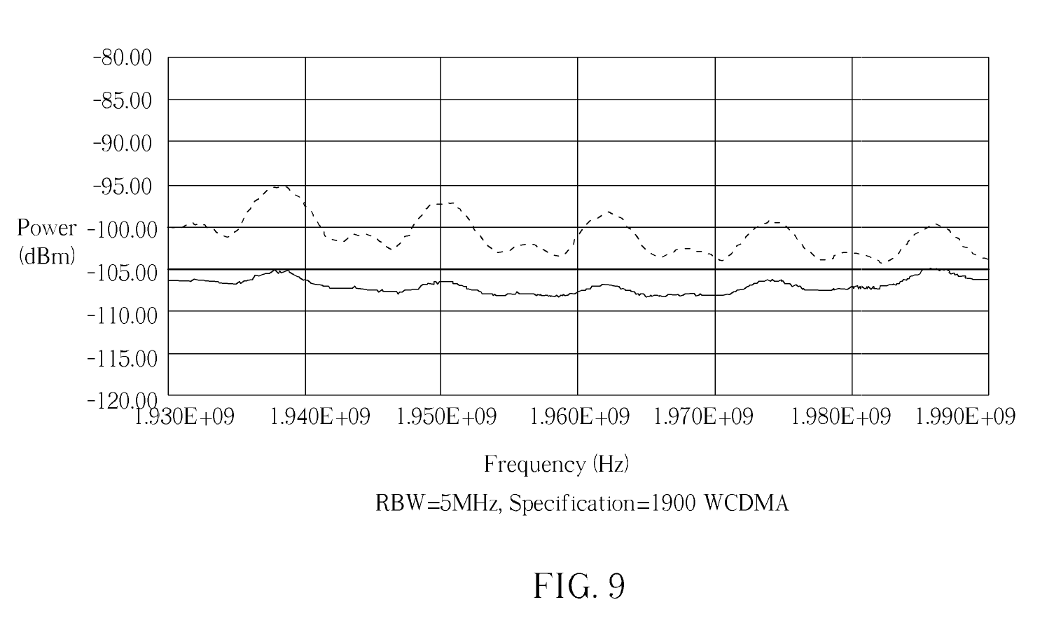

Please further refer to FIG. 8 and FIG. 9. FIG. 8 and FIG. 9 are schematic diagrams of experimental measurement results of the present invention. In FIG. 8 and FIG. 9, the horizontal axis and the vertical axis represent frequencies and power of the electromagnetic noises, of which units are Hz and dBm, respectively. In FIG. 8, the resolution bandwidth (RBW) of the spectrum analyzer 45 is set as 1.2 MHz, the horizontal line (−105 dBm) represents the noise standard of the mobile communications specification CDMA1900, and a solid line and a dashed line represent electromagnetic noise measurement results of the printed circuit board 20 that applies the metal conducting circuit 23 and the conventional metal conducting circuit 24, respectively. As shown in FIG. 8, the printed circuit board 20 applying the metal conducting circuit 23 of the present invention has a good noise suppression effect apparently, and can also conform to the noise standard of the mobile communications specification CDMA1900. In FIG. 9, the resolution bandwidth (RBW) of the spectrum analyzer 45 is set as 5 MHz, and the horizontal line (−105 dBm) represents the noise standard of the mobile communications specification WCDMA1900. In this case, the printed circuit board 20 applying the metal conducting circuit 23 of the present invention also has a good noise suppression effect when comparing with the conventional metal conducting circuit 24.

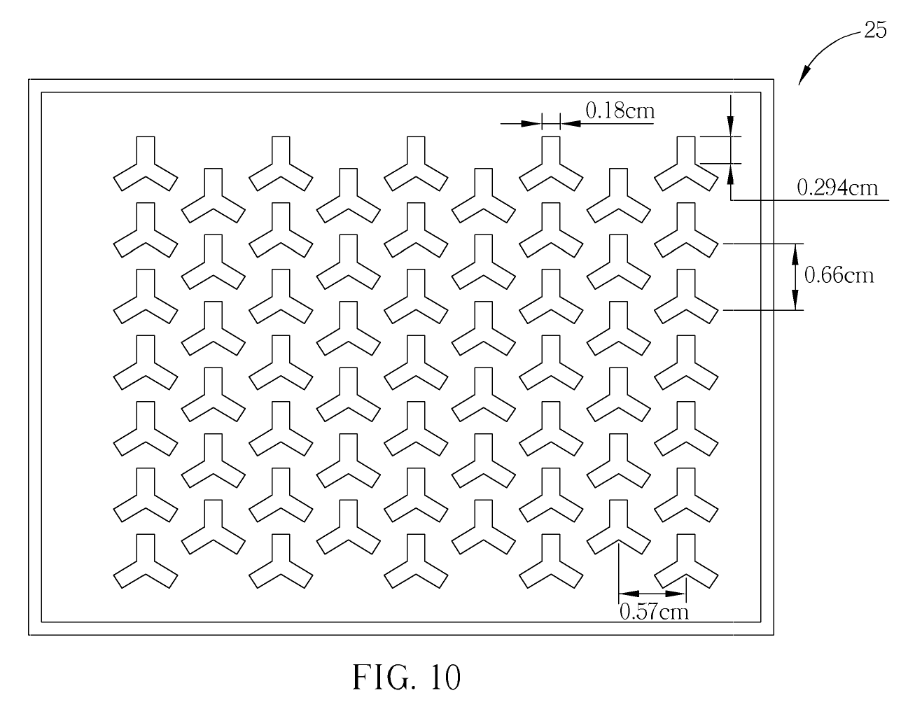

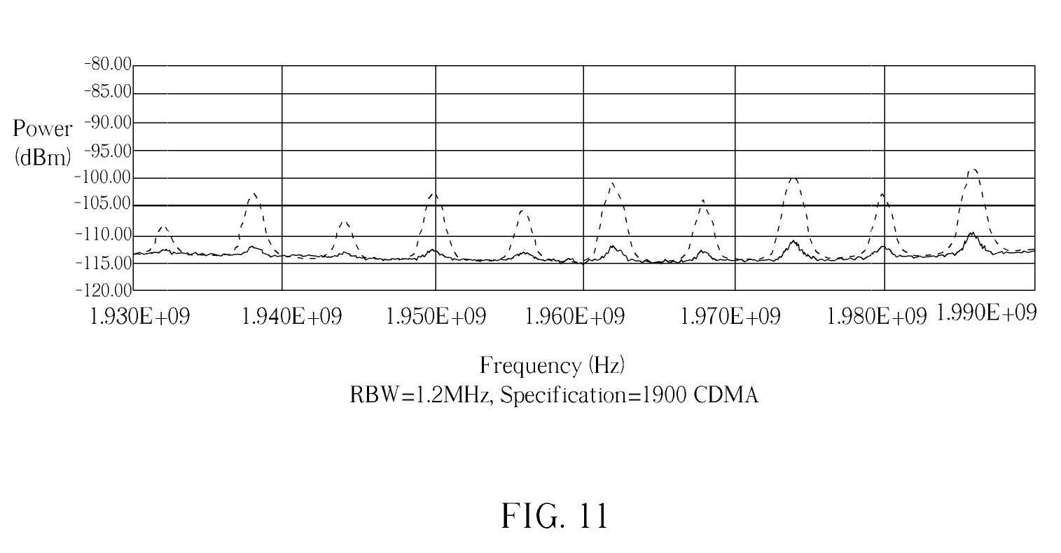

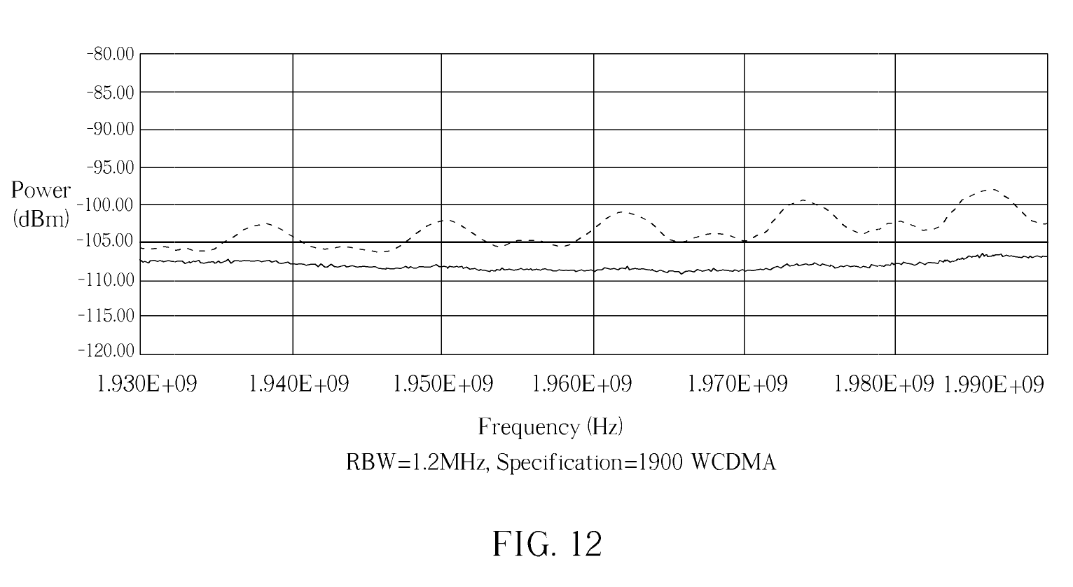

Please further refer to FIG. 10. FIG. 10 is a schematic diagram of a metal conducting circuit 25 of another embodiment of the present invention applied in the experiment of the present invention. Compared with the metal conducting circuit 23, the present invention etches slots with a shape similar to “λ” on the metal conducting circuit 25 to form periodically arranged pattern circuits. Dimensions corresponding to each part of the metal conducting circuit 25 are labeled in FIG. 10. In this embodiment, the conventional metal conducting circuit 24 is still utilized as an experimental reference group, and corresponding experimental results are shown in FIG. 11 and FIG. 12. In FIG. 11 and FIG. 12, dashed lines represent electromagnetic noise measurement results of the printed circuit board applying the conventional metal conducting circuit, and solid lines represent that when applying the metal conducting circuit 25 of the present invention. Similarly, the metal conducting circuit 25 including the periodically arranged pattern circuits also has a good suppression effect of the electromagnetic wave of noise.

As mentioned above, by forming the periodically arranged pattern circuits in the conducting layers of the printed circuit board, such as the power layers or the ground layers, the present invention can generate the electromagnetic wave stop band corresponding to the frequency of the electromagnetic noises for achieving the suppression effect of the electromagnetic waves of noise. Therefore, the present invention not only can save passive circuit components such as coupling capacitors and common mode chokes significantly, but also can reduce space requirements of the printed circuit board, so that the production cost can further be saved effectively.

Those skilled in the art will readily observe that numerous modifications and alterations of the device and method may be made while retaining the teachings of the invention.

What is claimed is:

1. A method for suppressing an electromagnetic wave of noise of a printed circuit board comprising:
forming a metal conducting circuit in a conducting layer of the printed circuit board; and
duplicating a plurality of pattern circuits, every two neighboring patterns with substantially the same patterns and separated space for forming a metal conducting circuit that is an electromagnetic wave suppressing circuit having an electromagnetic wave stop frequency band corresponding to the electromagnetic wave of noise.

2. The method of claim 1, wherein the printed circuit board is a multilayer printed circuit board.

3. The method of claim 1, wherein the conducting layer of the printed circuit board is a power layer of the printed circuit board.

4. The method of claim 1, wherein the conducting layer of the printed circuit board is a ground layer of the printed circuit board.

5. The method of claim 1, wherein the plurality of pattern circuits are equivalent to a filtering circuit corresponding to the electromagnetic wave stop frequency band.

6. The method of claim 1 further comprising determining dimensions of the plurality of pattern circuits according to wavelengths of the electromagnetic wave of noise.

7. The method of claim 6, wherein the dimensions of the plurality of pattern circuits and the wavelengths of the electromagnetic wave of noise have the same order of magnitude.

8. The method of claim 1 further comprising determining the separated space of the plurality of pattern circuits according to wavelengths of the electromagnetic wave of noise.

9. The method of claim 1 further comprising determining quantity of the plurality of pattern circuits according to frequencies of the electromagnetic wave of noise and a dimension of the printed circuit board.

10. A printed circuit board capable of suppressing an electromagnetic wave of noise comprising:
a conducting layer; and
a metal conducting circuit, laid in the conducting layer, forming a plurality of pattern circuits, every two neighboring patterns with substantially the same patterns and separated space for forming a metal conducting circuit that is an electromagnetic wave suppressing circuit having an electromagnetic wave stop frequency band corresponding to the electromagnetic wave of noise.

11. The printed circuit board of claim 10, wherein the printed circuit board is a multilayer printed circuit board.

12. The printed circuit board of claim 10, wherein the conducting layer of the printed circuit board is a power layer of the printed circuit board.

13. The printed circuit board of claim 10, wherein the conducting layer of the printed circuit board is a ground layer of the printed circuit board.

14. The printed circuit board of claim 10, wherein the plurality of pattern circuits are equivalent to a filtering circuit corresponding to the electromagnetic wave stop frequency band.

15. The printed circuit board of claim 10, wherein dimensions of the plurality of pattern circuits are corresponding to wavelengths of the electromagnetic wave of noise.

16. The printed circuit board of claim 15, wherein the dimensions of the plurality of pattern circuits and the wavelengths of the electromagnetic wave of noise have the same order of magnitude.

17. The printed circuit board of claim 10, wherein the separated space of the plurality of pattern circuits is corresponding to wavelengths of the electromagnetic wave of noise.

18. The printed circuit board of claim 10, wherein quantity of the plurality of pattern circuits is corresponding to frequencies of the electromagnetic wave of noise and a dimension of the printed circuit board.
